(19) United States
(12) Patent Application Publication
(10) Pub. No.: US 2026/0176503 A1
(43) Pub. Date: Jun. 25, 2026

(54) CONDUCTIVE ADHESIVE FILM, METHOD OF TREATING ADHEREND, AND METHOD OF MANUFACTURING SEMICONDUCTOR DEVICE

(71) Applicant: RESONAC CORPORATION, Minato-ku, Tokyo (JP)

(72) Inventors: Seiji KAI, Minato-ku, Tokyo (JP); Keiichi HATAKEYAMA, Minato-ku, Tokyo (JP); Naoki EBINA, Minato-ku, Tokyo (JP); Masayoshi NISHIMOTO, Minato-ku, Tokyo (JP); Tomohito MOROSAKI, Minato-ku, Tokyo (JP); Yukihiro IWANAGA, Minato-ku, Tokyo (JP); Miharu KOSHINO, Minato-ku, Tokyo (JP); Naohiro KIMURA, Minato-ku, Tokyo (JP)

(73) Assignee: RESONAC CORPORATION, Minato-ku, Tokyo (JP)

(21) Appl. No.: 18/861,396

(22) PCT Filed: May 27, 2024
(86) PCT No.: PCT/JP2024/019394

§ 371 Date: Oct. 29, 2024

(30) Foreign Application Priority Data
Jun. 2, 2023 (WO) PCT/JP2023/020722

(51) Int. Cl. C09J 9/02; C09J 5/00; C09J 7/29; H10P 72/70

(52) U.S. Cl. CPC C09J 9/02; C09J 5/00; C09J 7/29; H10P 72/7402; C09J 2203/37; C09J 2301/314; C09J 2301/416; C09J 2301/502

(57) ABSTRACT

A conductive adhesive film including an adhesive layer located on an adherend side, and a base material layer, in which a surface resistance value of the conductive adhesive film is from 1×10⁷ Ω/□ to 1×10¹² Ω/□.

### TECHNICAL FIELD

The present disclosure relates to a conductive adhesive film, a method of treating an adherend, and a method of manufacturing a semiconductor device.

### BACKGROUND ART

In a semiconductor manufacturing process, an electrostatic adsorption method is used as one method for fixing a semiconductor wafer onto a stage of an etching apparatus or the like in various processes such as etching, chemical vapor deposition (CVD), and physical vapor deposition (PVD). In this electrostatic adsorption method, a voltage is applied between a stage and the semiconductor wafer placed on the stage with a dielectric layer interposed therebetween, and the semiconductor wafer is adsorbed to the stage by an electrostatic force generated between the stage and the semiconductor wafer (see, for example, Japanese Patent Application Laid-Open (JP-A) No. H5-63062).

However, in this electrostatic adsorption method, in principle, since it is necessary to use a stage as one electrode and a workpiece (for example, a semiconductor wafer) as another electrode, an insulator as the workpiece cannot be adsorbed and fixed onto the stage.

For example, since an insulating substrate is used in devices such as silicon on sapphire (SOS) and silicon on insulator (SOI), a strong adsorption force as in the semiconductor wafer cannot be obtained, and the electrostatic adsorption method cannot be adopted. Since an insulating substrate such as a glass substrate is used also in a flat panel display (FPD), a digital video disc (DVD), and the like, similarly, the electrostatic adsorption method cannot be adopted.

Therefore, in the case of using an insulating support, a method has been proposed in which electrostatic chucking is performed with a conductive adhesive film interposed between a support on which a semiconductor wafer is provided and a stage (see, for example, Japanese Patent Application Nos. 4898199 and 5101449).

### SUMMARY OF INVENTION

### Technical Problem

An object of an aspect of the disclosure is to provide a novel conductive adhesive film, and a method of treating an adherend and a method of manufacturing a semiconductor device which use the conductive adhesive film.

### Solution to Problem

Means for solving the above problems include the following embodiments.

<1> A conductive adhesive film including:
an adhesive layer located on an adherend side; and
a base material layer,
in which a surface resistance value of the conductive adhesive film on a side opposite to the adhesive layer side is from 1×10⁷ Ω/□ to 1×10¹² Ω/□.

<2> A conductive adhesive film including:
an adhesive layer located on an adherend side; and
a base material layer,
in which the conductive adhesive film whose adhesive force to the adherend changes before and after the adhesive layer is irradiated with an active energy ray, is used for an electrostatic chuck.

<3> The conductive adhesive film according to <1>, which is used for an electrostatic chuck.

<4> The conductive adhesive film according to any one of <1> to <3>, further including a conductive layer on a side opposite to a surface of the base material layer on the adhesive layer side.

<5> The conductive adhesive film according to any one of <1> to <4>, in which a conductive layer is not disposed on a surface of the base material layer on the adhesive layer side.

<6> The conductive adhesive film according to any one of <1> to <5>, in which a surface resistance value of the conductive adhesive film on a side opposite to the adhesive layer side is from 2×10⁸ Ω/□ to 1×10¹² Ω/□.

<7> The conductive adhesive film according to any one of <1> to <6>, in which an elastic modulus of the base material layer at 23° C. is 3.5 GPa or less.

<8> The conductive adhesive film according to any one of <1> to <7>, in which a light transmittance of the conductive adhesive film is 85% or less at at least one wavelength included in a wavelength range of from 380 nm to 780 nm.

<9> A method of treating an adherend, including: bonding an adherend to the adhesive layer of the conductive adhesive film according to any one of <1> to <8>; and subjecting the adherend to a processing treatment while adsorbing and fixing the adherend to an adsorption stage by electrostatic adsorption.

<10> The method of treating an adherend according to <9>, in which the processing treatment is etching, CVD, or PVD.

<11> The method of treating an adherend according to <9> or <10>, in which the adherend contains at least one selected from the group consisting of glass, ceramics, quartz, and a compound semiconductor.

<12> The method of treating an adherend according to any one of <9> to <11>, in which an adhesive force of the conductive adhesive film to the adherend changes before and after the adhesive layer is irradiated with an active energy ray, and
the adherend is peeled off by irradiating the adhesive layer with the active energy ray after completion of the processing treatment.

<13> A method of manufacturing a semiconductor device, including: bonding an adherend to the adhesive layer of the conductive adhesive film according to any one of <1> to <8>; and subjecting the adherend to a processing treatment while adsorbing and fixing the adherend to an adsorption stage by electrostatic adsorption.

### Advantageous Effects of Invention

According to an aspect of the disclosure, there are provided a novel conductive adhesive film, and a method of treating an adherend and a method of manufacturing a semiconductor device which use the conductive adhesive film.

### BRIEF DESCRIPTION OF DRAWINGS

FIG. 1 is a view schematically illustrating a configuration of a conductive adhesive film.

### DESCRIPTION OF EMBODIMENTS

Hereinafter, modes for carrying out the disclosure will be described in detail. However, the disclosure is not limited to the following embodiments. In the following embodiments, constituent elements (including elemental steps and the like) are not necessarily indispensable unless otherwise stated. The same applies to numerical values and ranges thereof, and does not limit the disclosure.

In the disclosure, the term “step” includes not only a step independent of other steps but also a step by which an action of the step is achieved, though the step cannot be clearly distinguished from other steps.

In the disclosure, a numerical range that has been indicated by use of “to” includes the numerical values which are described before and after “to”, as a minimum value and a maximum value, respectively.

In a numerical range described in a stepwise manner in the disclosure, an upper limit value or a lower limit value described in one numerical range may be replaced with an upper limit value or a lower limit value described in another numerical range described in a stepwise manner. In a numerical range described in the disclosure, an upper limit value or a lower limit value of the numerical range may be replaced with a value shown in Examples.

In the disclosure, each component may contain a plurality of corresponding substances. In a case in which a plurality of substances corresponding to each component are present in the composition, the content ratio or content of each component means the total content ratio or content of the plurality of substances present in the composition unless otherwise specified.

In the disclosure, particles corresponding to each component may include a plurality of kinds of particles. In a case in which a plurality of kinds of particles corresponding to each component are present in a composition, the particle size of each component refers to the value of the particle size for a mixture of the plurality of kinds of particles present in the composition, unless otherwise specified.

In the disclosure, the term “layer” includes, in a case in which a region in which the layer is present is observed, not only a case in which the layer is formed over an entire area of the region, but also a case in which the layer is formed only in a part of the region.

In the disclosure, the thickness of the conductive adhesive film or each layer constituting the conductive adhesive film can be measured by a known method. For example, the thickness may be measured using a dial gauge or the like, or may be measured from a cross-sectional image of the conductive adhesive film. Alternatively, a material constituting the layer is removed using a solvent or the like, and the thickness may be calculated from the mass before and after removal, the density of the material, the area of the layer, and the like. In a case in which the thickness of the layer is not constant, an arithmetic average value of values measured at arbitrary five points is taken as the thickness of the layer.

In the disclosure, “(meth)acrylic” refers to either or both of acrylic and methacrylic, and “(meth)acrylate” refers to either or both of acrylate and methacrylate.

### <Conductive Adhesive Film>

A conductive adhesive film of the disclosure includes an adhesive layer located on an adherend side, and a base material layer, and a surface resistance value of the conductive adhesive film on a side opposite to the adhesive layer side satisfies from 1×10⁷ Ω/□ to 1×10¹² Ω/□.

The use application of the conductive adhesive film of the disclosure is not particularly limited, and can be used, for example, for an electrostatic chuck, and can be used in a case in which various processing treatments are performed in a state in which the adherend is adsorbed and fixed from the base material layer side in a state in which the adherend is bonded to the adhesive layer. The use application of the conductive adhesive film is not limited to an electrostatic chuck, and the conductive adhesive film may be used for a processing treatment performed by fixing an adherend other than the electrostatic chuck, production of electronic components, optical materials, and the like, temporary protection of the adherend, a dicing tape, and the like.

The adherend of the conductive adhesive film of the disclosure is not particularly limited, and examples thereof include a member containing at least one selected from the group consisting of glass, ceramics, quartz, and a compound semiconductor.

The adherend may have a configuration including a semiconductor wafer and a support provided on a surface on a side opposite to a processed surface of the semiconductor wafer. The support is a member for protecting the semiconductor wafer. The support may be, for example, a member composed of at least one selected from the group consisting of glass, ceramics, quartz, and a compound semiconductor.

The surface resistance value of the conductive adhesive film on a side opposite to the adhesive layer side may satisfy from 1×10⁷ Ω/□ to 1×10¹² Ω/□, and for example, preferably satisfies from 1×10⁷ Ω/□ to 1×10¹¹ Ω/□, and more preferably satisfies from 1×10⁷ Ω/□ to 1×10¹⁰ Ω/□.

The surface resistance value of the conductive adhesive film on a side opposite to the adhesive layer side may satisfy from 2×10⁸ Ω/□ to 1×10¹² Ω/□, or may satisfy from 1×10⁹Ω/□ to 1×10¹² Ω/□. Thereby, conduction with the adherend through the conductive adhesive film is suppressed, and damage due to electrostatic breakdown or the like of the adherend can be suppressed. For example, in a case in which the processing treatment of the adherend is performed in a state in which the adherend is adsorbed and fixed to an adsorption stage by an electrostatic chuck, the surface resistance value of the conductive adhesive film on a side opposite to the adhesive layer side satisfies from 1×10⁹ Ω/□ to 1×10¹² Ω/□, so that conduction with the adherend can be suppressed, and it is possible to suppress an adverse effect on the adherend such as damage due to electrostatic breakdown of the adherend at the time of bonding or peeling the conductive adhesive film.

### (Adhesive Layer)

The conductive adhesive film of the disclosure includes an adhesive layer located on an adherend side. The adhesive layer is provided by applying an adhesive on the base material layer or the conductive layer provided on the base material layer so as to have a predetermined thickness, and then drying or heating the adhesive. In a case in which the adhesive is applied, a general application method can be used, and a known method such as gravure coating, die head coating, reverse coating, comma coating, air knife coating, or wire bar coating can be used.

The type of the adhesive is not particularly limited, and examples thereof include an acrylic adhesive, a rubber-based adhesive, a vinyl alkyl ether-based adhesive, a silicone-based adhesive, a polyester-based adhesive, a polyamide-based adhesive, a urethane-based adhesive, a fluorine-based adhesive, and a styrene-diene block copolymer-based adhesive. Among them, the adhesive is more preferably an acrylic adhesive. The adhesive contained in the adhesive layer may be only one kind or two or more kinds.

Examples of the acrylic adhesive include an acrylic adhesive having, as a base polymer, an acrylic polymer (homopolymer or copolymer) using one kind or two or more kinds of (meth)acrylic acid alkyl esters as a monomer component.

Examples of the (meth)acrylic acid alkyl ester constituting the acrylic adhesive include (meth)acrylic acid alkyl esters such as methyl (meth)acrylate, ethyl (meth)acrylate, propyl (meth)acrylate, isopropyl (meth)acrylate, butyl (meth)acrylate, isobutyl (meth)acrylate, s-butyl (meth)acrylate, t-butyl (meth)acrylate, pentyl (meth)acrylate, hexyl (meth)acrylate, heptyl (meth)acrylate, octyl (meth)acrylate, 2-ethylhexyl (meth)acrylate, isooctyl (meth)acrylate, nonyl (meth)acrylate, isononyl (meth)acrylate, decyl (meth)acrylate, isodecyl (meth)acrylate, undecyl (meth)acrylate, dodecyl (meth)acrylate, tridecyl (meth)acrylate, tetradecyl (meth)acrylate, pentadecyl (meth)acrylate, hexadecyl (meth)acrylate, heptadecyl (meth)acrylate, octadecyl (meth)acrylate, nonadecyl (meth)acrylate, and eicosyl(meth)acrylate. The alkyl group of the (meth)acrylic acid alkyl ester may be linear or branched.

The acrylic polymer may include a structural unit derived from another monomer component (copolymerizable monomer component) copolymerizable with a (meth)acrylic acid alkyl ester if necessary, for the purpose of modifying cohesive force, heat resistance, crosslinkability, and the like. Examples of such a copolymerizable monomer component include carboxyl group-containing monomers such as (meth)acrylic acid (acrylic acid, methacrylic acid), carboxyethyl acrylate, carboxypentyl acrylate, itaconic acid, maleic acid, fumaric acid, and crotonic acid; acid anhydride group-containing monomers such as maleic anhydride and itaconic anhydride; hydroxyl group-containing monomers such as hydroxyethyl (meth)acrylate, hydroxypropyl (meth)acrylate, hydroxybutyl (meth)acrylate, hydroxyhexyl (meth)acrylate, hydroxyoctyl (meth)acrylate, hydroxydecyl (meth)acrylate, hydroxylauryl (meth)acrylate, and (4-hydroxymethylcyclohexyl)methyl methacrylate; sulfonic acid group-containing monomers such as styrenesulfonic acid, allylsulfonic acid, 2-(meth)acrylamide-2-methylpropanesulfonic acid, (meth)acrylamide propanesulfonic acid, sulfopropyl (meth)acrylate, and (meth)acryloyloxy naphthalenesulfonic acid; phosphoric acid group-containing monomers such as 2-hydroxyethyl acryloyl phosphate; (N-substituted)amide-based monomers such as (meth)acrylamide, N,N-dimethyl (meth)acrylamide, N-butyl (meth)acrylamide, N-methylol (meth)acrylamide, and N-methylol propane (meth)acrylamide; aminoalkyl (meth)acrylate-based monomer such as aminoethyl (meth)acrylate, N,N-dimethylaminoethyl (meth)acrylate, and t-butylaminoethyl (meth)acrylate; alkoxyalkyl (meth)acrylate-based monomers such as methoxyethyl (meth)acrylate and ethoxyethyl (meth)acrylate; cyanoacrylate monomers such as acrylonitrile and methacrylonitrile; epoxy group-containing acrylic monomers such as glycidyl (meth)acrylate; styrene-based monomers such as styrene and α-methylstyrene; vinyl ester-based monomers such as vinyl acetate and vinyl propionate; olefin-based monomers such as isoprene, butadiene, and isobutylene; vinyl ether-based monomers such as vinyl ether; nitrogen-containing monomers such as N-vinylpyrrolidone, methylvinylpyrrolidone, vinylpyridine, vinylpiperidone, vinylpyrimidine, vinylpiperazine, vinylpyrazine, vinylpyrrole, vinylimidazole, vinyloxazole, vinylmorpholine, N-vinylcarboxylic acid amides, and N-vinylcaprolactam; maleimide-based monomers such as N-cyclohexylmaleimide, N-isopropylmaleimide, N-laurylmaleimide, and N-phenylmaleimide; itaconimide-based monomers such as N-methyl itaconimide, N-ethyl itaconimide, N-butyl itaconimide, N-octyl itaconimide, N-2-ethylhexyl itaconimide, N-cyclohexyl itaconimide, and N-lauryl itaconimide; succinimide-based monomers such as N-(meth)acryloyloxymethylene succinimide, N-(meth)acryloyl-6-oxyhexamethylene succinimide, and N-(meth)acryloyl-8-oxyoctamethylene succinimide; glycol-based acrylic ester monomers such as polyethylene glycol (meth)acrylate, polypropylene glycol (meth)acrylate, methoxyethylene glycol (meth)acrylate, and methoxypolypropylene glycol (meth)acrylate; acrylic acid ester-based monomers having a heterocyclic ring, a halogen atom, a silicon atom, or the like such as tetrahydrofurfuryl (meth)acrylate, fluorine (meth)acrylate, and silicone (meth)acrylate; and polyfunctional monomers such as hexanediol di(meth)acrylate, (poly)ethylene glycol di(meth)acrylate, (poly)propylene glycol di(meth)acrylate, neopentyl glycol di(meth)acrylate, pentaerythritol di(meth)acrylate, trimethylolpropane tri(meth)acrylate, pentaerythritol tri(meth)acrylate, dipentaerythritol hexa(meth)acrylate, epoxy acrylate, polyester acrylate, urethane acrylate, divinylbenzene, butyl di(meth)acrylate, and hexyl di(meth)acrylate. These copolymerizable monomer components may be used singly, or in combination of two or more kinds thereof.

The acrylic copolymer may be a crosslinked acrylic copolymer. The crosslinked acrylic copolymer can be synthesized by crosslinking a monomer as a raw material of the acrylic copolymer using a crosslinking agent. Examples of the crosslinking agent used for the synthesis of the crosslinked acrylic copolymer include known crosslinking agents such as an isocyanate compound, a melamine compound, and an epoxy compound. The crosslinking agent may be a polyfunctional crosslinking agent such as a trifunctional or tetrafunctional crosslinking agent in order to form a gently spread network structure in the acrylic adhesive.

The adhesive layer may contain another component which is other than the adhesive or the crosslinking agent. Examples of another component include a tackifying resin, a colorant, a thickener, an extender, a filler, a plasticizer, an antiaging agent, an antioxidant, and a surfactant.

In the conductive adhesive film of the disclosure, a separator may be provided on a surface of the adhesive layer on the adherend side. Examples of the separator include resin films made of polyethylene terephthalate (PET), polyethylene, polypropylene, or the like, resin films or paper, which is surface-coated with a release agent such as a silicone-based release agent, a fluorine-based release agent, or a long-chain alkyl acrylate-based release agent.

A thickness of the adhesive layer is not particularly limited, and may be, for example, 3 μm or more or may be 5 μm or more. The thickness of the adhesive layer may be, for example, 50 μm or less or may be 30 μm or less.

### (Base Material Layer)

The conductive adhesive film of the disclosure includes a base material layer. The base material layer is a layer for supporting the adherend with the adhesive layer interposed therebetween. The surface resistance value of the conductive adhesive film of the disclosure on a side opposite to the adhesive layer side may be adjusted by adjusting the material, composition, and the like of the base material layer.

The material of the base material layer is not particularly limited. Examples thereof include polyolefins such as polyethylene and polypropylene, polyesters such as polyethylene terephthalate, polybutylene terephthalate, polyethylene naphthalate, and resins such as polyimide, polyamide, polyester ether, polyamideimide, fluorine-containing resins, and thermoplastic elastomers. Among them, polyolefins such as polyethylene and polypropylene, and polyethylene terephthalate are preferable, and from the viewpoint of followability to the adherend and detection by an optical sensor, polyolefins such as polyethylene and polypropylene are more preferable. From the viewpoint of reducing an elastic modulus of the base material layer and improving the followability to the adherend, it is preferable that the base material layer does not contain a polyimide (for example, a polyimide containing a biphenylimide ring).

The resin contained in the base material layer may be only one kind or two or more kinds thereof.

The base material layer may be a layer composed of the above-described resin, or may contain another component which is other than the resin. Examples of another component that can be contained in the base material layer include the above-described other component that can be contained in the adhesive layer, an antistatic agent described later, a conductive polymer material, and a conductive material such as a metal.

The base material layer may be subjected to a stretching treatment, and is not necessarily subjected to a stretching treatment. In a case in which a stretching treatment is performed, there is a tendency that the strength of the conductive adhesive film is excellent, and in a case in which a stretching treatment is not performed, there is a tendency that the stretchability of the conductive adhesive film is excellent.

A thickness of the base material layer is not particularly limited, and is preferably 10 μm or more, more preferably 20 μm or more, and still more preferably 30 μm or more. In a case in which the thickness of the base material layer is 10 μm or more, the base material is hardly broken, and in a case in which the thickness of the base material layer is 30 μm or more, handleability is more excellent.

The thickness of the base material layer is preferably 300 μm or less, more preferably 200 μm or less, and still more preferably 100 μm or less. In a case in which the thickness of the base material layer is 300 μm or less, followability to the adherend (a property of being deformed according to the shape of the adherend) can be sufficiently obtained.

An elastic modulus of the base material layer at 23° C. is not particularly limited, and is preferably 3.5 GPa or less, more preferably 2.0 GPa or less, still more preferably 1.5 GPa or less, and particularly preferably 1.0 GPa or less. In a case in which the elastic modulus of the base material layer at 23° C. is 3.5 GPa or less, there is a tendency that followability to the adherend (a property of being deformed according to the shape of the adherend) can be sufficiently obtained.

The base material layer may be composed of only one layer or two or more layers. Examples of the method of obtaining a base material layer composed of two or more layers include a method of extruding a material of each layer by a co-extrusion method to produce a base material layer, and a method of laminating two or more films.

In a case in which a release film includes a conductive layer, a surface of the base material layer on a side where the conductive layer is provided may be subjected to a treatment for improving the adhesive force to the conductive layer. Examples of the treatment method include surface treatments such as a corona treatment and a plasma treatment, and application of an undercoating agent (primer).

If necessary, a back surface treatment agent for adjusting the unwinding property of the release film from a roll may be applied to a back surface of the base material layer (a surface opposite to a side to be bonded to a bonding surface). Examples of the back surface treatment agent include a silicone resin, a fluorine-containing resin, polyvinyl alcohol, and a resin having an alkyl group. If necessary, these back surface treatment agents may be subjected to a modification treatment. The back surface treatment agent may be used singly or in combination of two or more kinds thereof.

### (Conductive Layer)

The conductive adhesive film of the disclosure may further include a conductive layer. The position of the conductive layer is not particularly limited, and the conductive layer may be disposed between the adhesive layer and the base material layer, and the conductive layer may be disposed on a side opposite to a surface of the base material layer on the adhesive layer side.

In the conductive film of the disclosure, the conductive layer is not an essential layer. For example, from the viewpoint of making the surface resistance value of the conductive adhesive film on a side opposite to the adhesive layer side easily satisfy from 1×10⁷ Ω/□ to 1×10¹² Ω/□, the conductive layer may be provided.

A surface resistance value of the conductive layer may satisfy from 1×10⁷ Ω/□ to 1×10¹² Ω/□, and for example, preferably satisfies from 1×10⁷ Ω/□ to 1×10¹¹ Ω/□, and more preferably satisfies from 1×10⁷ Ω/□ to 1×10¹⁰ Ω/□.

The surface resistance value of the conductive layer may satisfy from 1×10⁹ Ω/□ to 1×10¹² Ω/□.

The conductive layer may be disposed between the adhesive layer and the base material layer and on both sides opposite to the surface of the base material layer on the adhesive layer side. In this case, the adhesive layer, the conductive layer, the base material layer, and the conductive layer may be disposed in this order. The compositions of the two conductive layers may be the same as or different from each other.

Alternatively, the conductive layer may be disposed between the adhesive layer and the base material layer, and only on one side opposite to the surface of the base material layer on the adhesive layer side. In this case, the adhesive layer, the conductive layer, the base material layer, and the conductive layer may be disposed in this order (provided that the conductive layer is not disposed outside the base material layer), and the adhesive layer, the base material layer, and the conductive layer may be disposed in this order (provided that the conductive layer is not disposed between the adhesive layer and the base material layer).

In a case in which the conductive layer is disposed between the adhesive layer and the base material layer, depending on the compatibility with the adhesive layer, a possibility is conceivable that the conductive layer is deposited on the surface of the adhesive layer to affect the adherend in a case in which the adhesive layer is bonded to the adherend (for example, there is a possibility that the residue of the conductive layer adheres to the adherend). Therefore, it is preferable that the conductive layer is disposed only on one side opposite to the surface of the base material layer on the adhesive layer side, and it is preferable that the conductive layer is not disposed on the surface of the base material layer on the adhesive layer side.

The configuration of the conductive layer is not particularly limited as long as the conductive layer can enhance the conductivity of the conductive adhesive film to suppress charging. For example, the conductive layer may be a layer containing an antistatic agent, or a conductive material such as a metal or a conductive polymer material. The conductive layer is provided by applying a conductive layer forming material containing a conductive material to the base material layer so as to have a predetermined thickness, and then drying or heating the adhesive. In the application of the conductive layer forming material, a general application method can be used as in the application of the adhesive.

Examples of the antistatic agent contained in the conductive layer include a cationic antistatic agent having a cationic group such as a quaternary ammonium salt, a pyridinium salt, or a primary to tertiary amino group, an anionic antistatic agent having an anionic group such as a sulfonate group, a sulfate group, or a phosphate group, an amphoteric antistatic agent such as an amino acid-based or amino acid sulfate-based antistatic agent, a nonionic antistatic agent having a nonionic group such as an amino alcohol-based, glycerin-based, or polyethylene glycol-based antistatic agent, and a polymer-type antistatic agent prepared by increasing the molecular weight of these antistatic agents. The antistatic agent may be a combination of a main agent and an auxiliary agent (curing agent or the like).

Examples of the conductive polymer material contained in the conductive layer include polymer compounds having polythiophene, polyaniline, polypyrrole, polyacetylene, or the like in the skeleton.

Examples of the metal include aluminum, copper, gold, chromium, and tin, and from the viewpoint of availability, aluminum is preferable.

The method of forming a conductive layer is not particularly limited. Examples thereof include a method of laminating a metal foil or the like on one surface of a film to be a base material layer, and a method of applying a material of a conductive layer to one surface of a film to be a base material layer by coating, vapor deposition, or the like.

A thickness of the conductive layer is not particularly limited as long as the antistatic effect of the conductive adhesive film can be sufficiently obtained. For example, the thickness may be within a range of from 0.01 μm to 1 μm.

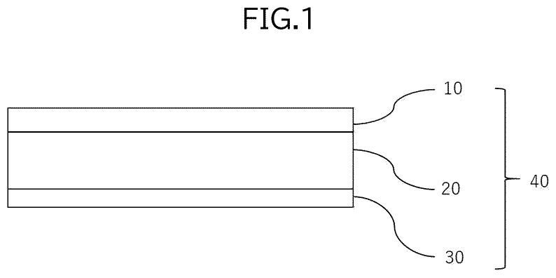

An example of a configuration of a conductive adhesive film including an adhesive layer, a base material layer, and a conductive layer is schematically illustrated in FIG. 1. A conductive adhesive film 40 illustrated in FIG. 1 includes an adhesive layer 10, a base material layer 20, and a conductive layer 30 in this order.

The entire thickness of the conductive adhesive film is not particularly limited, and can be set according to desired physical properties (such as elongation rate, elastic modulus, and resistivity). For example, the entire thickness may be from 30 μm to 300 μm, from 35 μm to 250 μm, or from 40 μm to 200 μm.

A light transmittance of the conductive adhesive film of the disclosure in a visible light region may be 98% or less or may be 85% or less. In a case in which the light transmittance is 70% or less, detection by light irradiation becomes easy. The light transmittance of the conductive adhesive film of the disclosure in the visible light region may be 0% or more.

The visible light region refers to, for example, a range of from 380 nm to 780 nm. The light transmittance of the conductive adhesive film may satisfy the above-described range (for example, 85% or less) at at least one wavelength included in the wavelength range.

### Modification

A modification of the conductive adhesive film of the disclosure may be a conductive adhesive film including an adhesive layer located on an adherend side, and a base material layer, in which the conductive adhesive film whose adhesive force to the adherend changes before and after the adhesive layer is irradiated with an active energy ray, is used for an electrostatic chuck. In a case in which the adhesive force to the adherend changes (for example, decreases) before and after the adhesive layer is irradiated with an active energy ray, peeling of the adherend after completion of the processing treatment of the adherend becomes easy, and handleability is excellent.

The active energy ray is not particularly limited as long as the adhesive force of the adhesive layer to the adherend can be changed by irradiation, and examples thereof include ultraviolet rays, visible rays, and electron beams.

The conductive adhesive film of the modification may satisfy the above-described configuration or preferable configuration of the conductive adhesive film. For example, in the conductive adhesive film of the modification, the surface resistance value may satisfy from 1×10⁷ Ω/□ to 1×10¹² Ω/□.

In the conductive adhesive film of the modification, the type of the adhesive is not particularly limited, and the adhesive exemplified in the conductive adhesive film of the disclosure described above can be suitably used. In particular, the adhesive is preferably an acrylic adhesive.

### <Method of Treating Adherend and Method of Manufacturing Semiconductor Device>

A method of treating an adherend of the disclosure is a method of treating an adherend, including: bonding an adherend to the adhesive layer of the above-described conductive adhesive film of the disclosure; and subjecting the adherend to a processing treatment while adsorbing and fixing the adherend to an adsorption stage by electrostatic adsorption. A semiconductor device may be manufactured by subjecting an adherend to a processing treatment.

In the method of treating an adherend of the disclosure, the adherend is bonded to the adhesive layer of the conductive adhesive film, and the adherend to which the conductive adhesive film is bonded is disposed on an adsorption stage installed in a vacuum chamber such as a dry etching apparatus. The adherend adsorbed and fixed to the adsorption stage is subjected to a processing treatment.

Examples of the adherend include a member containing at least one selected from the group consisting of glass, ceramics, quartz, and a compound semiconductor. An example of the adherend includes a laminated body in which a support for supporting a semiconductor substrate is attached to the semiconductor substrate having an electronic device formed on a surface thereof. The support may be a member containing at least one selected from the group consisting of glass, ceramics, quartz, and a compound semiconductor.

After the adherend is placed on the adsorption stage, a voltage is applied to an internal electrode provided inside the adsorption stage to generate positive and negative charges on the surfaces of the conductive adhesive film and the adsorption stage, and the adherend can be adsorbed and fixed to the adsorption stage by the electrostatic force acting therebetween.

Examples of the processing treatment performed with respect to the adherend adsorbed and fixed to the adsorption stage include etching, chemical vapor deposition (CVD), and physical vapor deposition (PVD).

In the case of using the conductive adhesive film whose adhesive force to the adherend changes before and after the adhesive layer is irradiated with an active energy ray, the adherend may be peeled off by irradiating the adhesive layer with the active energy ray after completion of the processing treatment.

After the peeled adherend is taken out from a vacuum chamber such as a dry etching apparatus, a treatment such as washing may be performed.

### EXAMPLES

Hereinafter, the conductive adhesive film of the disclosure will be described based on Examples. However, the disclosure is not limited to the following Examples.

### Examples 1 to 4

As a base material layer, a film having one surface subjected to a corona treatment as shown in Table 1 was prepared.

An adhesive having the composition of the adhesive layer shown in Table 1 was applied to the corona-treated surface of the base material layer, and heated at 100° C. for 1 minute to form an adhesive layer having a thickness of 10 μm or 20 μm. As the adhesive, one obtained by diluting the total of the components in Table 1 to 10% by mass using toluene/methyl ethyl ketone (MEK) (8/2 (mass ratio)) was used.

A conductive layer forming material having a composition of a conductive layer shown in Table 1 was applied to a surface on a side opposite to the corona-treated surface of the base material layer, and heated at 100° C. for 1 minute to form a conductive layer having a thickness of 0.2 μm. As the conductive layer forming material, one obtained by diluting the total of the components in Table 1 to 1.65% by mass or 2.0% by mass using methanol was used.

The separator shown in Table 1 was bonded to the adhesive layer provided on the base material layer.

As described above, a conductive adhesive film in which the separator, the adhesive layer, the base material layer, and the conductive layer were layered in this order was obtained.

The elastic modulus at 23° C. of each base material layer is as follows.
Polypropylene: 0.7 GPa
Polyolefin: 0.1 GPa
Polyethylene terephthalate: 3.4 GPa

### Comparative Example 1

The same operation as in Example 3 was performed except that the conductive layer was not formed. As a result, an adhesive film in which the separator, the adhesive layer, and the base material layer were layered in this order was obtained.

The following evaluation test was performed using the conductive adhesive film and the adhesive film thus obtained. The results are shown in Table 1.

### <Si Wafer Characteristics>

The separators of the conductive adhesive film and the adhesive film were peeled off, and the adhesive characteristics (Si wafer characteristics) in a case in which a Si wafer was bonded to the adhesive layer was evaluated.

Specifically, the 180° peel strength (gf/25 mm) of the Si wafer was measured under the conditions of 23° C. and a tensile rate of 300 mm/min. This value was taken as the adhesive force at 23° C. The results are shown in Table 1.

After the Si wafer was bonded to the adhesive layer, the conductive adhesive film after bonding the Si wafer was heated at 110° C. for 1 hour. Thereafter, the 180° peel strength (gf/25 mm) of the Si wafer was measured under the conditions of 23° C. and a tensile rate of 300 mm/min. This value was taken as the adhesive force after 1 hour at 110° C. The results are shown in Table 1.

After the Si wafer was bonded to the adhesive layer, the conductive adhesive film and the adhesive film after bonding the Si wafer were stored at 23° C. for 14 days. Whether or not lifting of the Si wafer with respect to the adhesive layer occurred after storage was evaluated. The results are shown in Table 1.

### <Glass Characteristics>

The separator of the conductive adhesive film was peeled off, and the adhesive characteristics (glass characteristics) in a case in which glass was bonded to the adhesive layer was evaluated.

Specifically, the 180° peel strength (gf/25 mm) of the glass was measured under the conditions of 23° C. and a tensile rate of 300 mm/min. This value was taken as the adhesive force at 23° C. The results are shown in Table 1.

After the glass was bonded to the adhesive layer, the conductive adhesive film after bonding the glass was heated at 110° C. for 1 hour. Thereafter, the 180° peel strength (gf/25 mm) of the glass was measured under the conditions of 23° C. and a tensile rate of 300 mm/min. This value was taken as the adhesive force after 1 hour at 110° C. The results are shown in Table 1.

### <Surface Resistance Value>

The surface resistance value of each of the conductive adhesive film and the side of the conductive adhesive film opposite to the adhesive layer side was measured using an insulation resistance meter (digital ultra-high resistance/micro ammeter manufactured by Advantest Corporation). Specifically, after the conductive adhesive film and the adhesive film were left to stand for 1 hour or longer in an atmosphere of 23±2° C. and a humidity of 55% RH, the surface resistance value (Ω) after applying a voltage of 500 V for 1 minute was measured, and the surface resistance value (Ω/□) was calculated using the following formula. The results are shown in Table 1. In Table 1, α.E+0β and α.E+β (α and β are integers) mean α×10^{β}.

$$Surface resistance value = π ( D + d ) / ( D - d ) \times R$$

π: circumferential ratio, D: inner diameter of ring-shaped electrode, d: outer diameter of ring-shaped electrode, R: surface resistance value

The value of π(D+d)/(D−d) used for calculation of the surface resistance value was 18.84.

### <Light Transmittance (%)>

The light transmittance (%) with respect to a three-layer layered structure of the adhesive layer, the base material layer, and the conductive layer used in each Example and Comparative Example was measured using a red LED (wavelength: about 650 nm). The results are shown in Table 1.

<Surface Roughness (μm)>

The surface roughness (arithmetic average roughness Ra) with respect to the base material layer used in each Example and Comparative Example was measured using a surface roughness measuring machine (Model SE3500, Kosaka Laboratory Ltd.). The results are shown in Table 1.

### <Electrostatic Chuck Evaluation>

The separators of the conductive adhesive film and the adhesive film were peeled off, a quartz substrate as an adherend was bonded to the adhesive layer, and electrostatic chuck evaluation was performed as follows.

An attempt was made to apply a voltage between the stage and the conductive adhesive film or the adhesive film disposed on the stage in a state in which the adherend was bonded to the adhesive layer, and to adsorb the adherend to the stage by the electrostatic force generated between the stage and the conductive adhesive film or the adhesive film. At this time, in a case in which the leakage amount of He for cooling the adherend was less than 10 Pa/min, the electrostatic chuck evaluation was A (Favorable), and in a case in which the leakage amount of He was 10 Pa/min or more, the electrostatic chuck evaluation was B (Poor). The results are shown in Table 1.

### <Optical Sensor Detection Evaluation>

The separators of the conductive adhesive film and the adhesive film were peeled off, a quartz substrate as an adherend was bonded to the adhesive layer, and optical sensor detection evaluation was performed as follows. In the optical sensor detection evaluation, in the thickness direction of the conductive adhesive film and the adhesive film, a region to which the adherend was bonded was irradiated with light from the thickness direction, and whether or not the substrate could be detected by an optical sensor during transporting the substrate was evaluated. A case in which detection was possible was evaluated as A, and a case in which detection was possible but detection was difficult was evaluated as B. The results are shown in Table 1.

TABLE 1

| | | | | | Comparative | |
|---|---|---|---|---|---|---|
| | | Example 1 | Example 2 | Example 3 | Example 1 | Example 4 |
| Adhesive layer | Acrylic adhesive | 100 | 100 | 100 | 100 | 100 |
| | Isocyanate-based crosslinking agent 1 | 12 | 8 | 12 | 12 | — |
| | (DURANATE E405-80T, Asahi Kasei | | | | | |
| | Corporation) | | | | | |
| | Isocyanate-based crosslinking agent 2 | — | — | — | — | 3.5 |
| | (DURANATE D201, Asahi Kasei | | | | | |
| | Corporation) | | | | | |
| | Thickness (μm) | 10 | 10 | 10 | 10 | 20 |
| Conductive layer | Polythiophene-based conductive | 27.2 | 27.2 | — | — | 27.2 |
| | polymer | | | | | |
| | Urethane-acrylic composite resin | 62.4 | 62.4 | — | — | 62.4 |
| | emulsion | | | | | |
| | Acrylic copolymer resin | — | — | 10.9 | — | — |
| | Epoxy resin | — | — | 2.7 | — | — |
| | Concentration (% by mass) of | 1.65 | 1.65 | 2.0 | 0.0 | 1.65 |
| | conductive layer forming material | | | | | |
| Base material | Polypropylene | ◯ | ◯ | — | — | — |
| layer | Polyolefin | — | — | ◯ | ◯ | |
| | Polyethylene terephthalate | — | — | — | — | ◯ |
| | Thickness (μm) of base material layer | 40 | 40 | 100 | 100 | 38 |
| Separator | Polyethylene | ◯ | ◯ | — | — | — |
| | Polyethylene terephthalate | — | — | ◯ | ◯ | ◯ |
| | Thickness (μm) of separator | 25 | 25 | 25 | 25 | 25 |
| Si wafer | Adhesive force at 23° C. (gf/25 mm) | 25.0 | 50.0 | 23.0 | 23.0 | 105.0 |
| characteristics | Adhesive force after 1 hour at 110° C. | 45.0 | 240.0 | 60.0 | 60.0 | 270.0 |
| | (gf/25 mm) | | | | | |
| | Lifting of Si wafer after 14 days at | Absent | Absent | Absent | Absent | Absent |
| | 23° C. | | | | | |
| Glass | Adhesive force at 23° C. (gf/25 mm) | 22.0 | 45.0 | 24.0 | 24.0 | 71.5 |
| characteristics | Adhesive force after 1 hour at 110° C. | 45.0 | 80.0 | 70.0 | 70.0 | 128.0 |
| | (gf/25 mm) | | | | | |
| Surface | 500 V-1 min application (Ω/□) | 3.3.E+08 | 5.2.E+08 | 1.5.E+09 | 1.5.E+14 | 4.5.E+08 |
| resistance value | | | | | | |

| | | | | | |
|---|---|---|---|---|---|
| Light transmittance (%) red LED | 71% | 71% | 46% | 46% | 86% |
| Surface roughness (μm) | 0.32 | 0.32 | 0.34 | 0.34 | 0.06 |
| Electrostatic chuck evaluation | A | A | A | B | A |
| Optical sensor detection evaluation | A | A | A | A | B |

As shown in Table 1, in Examples 1 to 4, the electrostatic chuck evaluation was favorable, and particularly, in Examples 1 to 3, the optical sensor detection evaluation was also favorable.

However, in Comparative Example 1, the electrostatic chuck evaluation was poor.

The entire contents of the disclosures by PCT/JP2023/020722 filed on Jun. 2, 2023 are incorporated herein by reference.

All the literature, patent application, and technical standards cited herein are also herein incorporated to the same extent as provided for specifically and severally with respect to an individual literature, patent application, and technical standard to the effect that the same should be so incorporated by reference.

1. A conductive adhesive film comprising:
an adhesive layer located on an adherend side; and
a base material layer,
wherein a surface resistance value of the conductive adhesive film on a side opposite to the adhesive layer side is from 1×10⁷ Ω/□ to 1×10¹² Ω/□.

2. A conductive adhesive film comprising:
an adhesive layer located on an adherend side; and
a base material layer,
wherein the conductive adhesive film whose adhesive force to the adherend changes before and after the adhesive layer is irradiated with an active energy ray, is used for an electrostatic chuck.

3. The conductive adhesive film according to claim 1, which is used for an electrostatic chuck.

4. The conductive adhesive film according to claim 1, further comprising a conductive layer on a side opposite to a surface of the base material layer on the adhesive layer side.

5. The conductive adhesive film according to claim 1, wherein a conductive layer is not disposed on a surface of the base material layer on the adhesive layer side.

6. The conductive adhesive film according to claim 1, wherein a surface resistance value of the conductive adhesive film on a side opposite to the adhesive layer side is from 2×10⁸ Ω/□ to 1×10¹² Ω/□.

7. The conductive adhesive film according to claim 1, wherein an elastic modulus of the base material layer at 23° C. is 3.5 GPa or less.

8. The conductive adhesive film according to claim 1, wherein a light transmittance of the conductive adhesive film is 85% or less at least one wavelength included in a wavelength range of from 380 nm to 780 nm.

9. A method of treating an adherend, comprising: bonding an adherend to the adhesive layer of the conductive adhesive film according to claim 1; and subjecting the adherend to a processing treatment while adsorbing and fixing the adherend to an adsorption stage by electrostatic adsorption.

10. The method of treating an adherend according to claim 9, wherein the processing treatment is etching, CVD, or PVD.

11. The method of treating an adherend according to claim 9, wherein the adherend contains at least one selected from the group consisting of glass, ceramics, quartz, and a compound semiconductor.

12. The method of treating an adherend according to claim 9, wherein an adhesive force of the conductive adhesive film to the adherend changes before and after the adhesive layer is irradiated with an active energy ray, and
the adherend is peeled off by irradiating the adhesive layer with the active energy ray after completion of the processing treatment.

13. A method of manufacturing a semiconductor device, comprising: bonding an adherend to the adhesive layer of the conductive adhesive film according to claim 1; and subjecting the adherend to a processing treatment while adsorbing and fixing the adherend to an adsorption stage by electrostatic adsorption.

14. The conductive adhesive film according to claim 2, further comprising a conductive layer on a side opposite to a surface of the base material layer on the adhesive layer side.

15. The conductive adhesive film according to claim 2, wherein a conductive layer is not disposed on a surface of the base material layer on the adhesive layer side.

16. The conductive adhesive film according to claim 2, wherein a surface resistance value of the conductive adhesive film on a side opposite to the adhesive layer side is from 2×10⁸ Ω/□ to 1×10¹² Ω/□.

17. The conductive adhesive film according to claim 2, wherein an elastic modulus of the base material layer at 23° C. is 3.5 GPa or less.

18. The conductive adhesive film according to claim 2, wherein a light transmittance of the conductive adhesive film is 85% or less at at least one wavelength included in a wavelength range of from 380 nm to 780 nm.

19. A method of treating an adherend, comprising: bonding an adherend to the adhesive layer of the conductive adhesive film according to claim 2; and subjecting the adherend to a processing treatment while adsorbing and fixing the adherend to an adsorption stage by electrostatic adsorption.

20. The method of treating an adherend according to claim 19, wherein the processing treatment is etching, CVD, or PVD.
